(19) United States
(12) Patent Application Publication
(10) Pub. No.: US 2026/0052667 A1
(43) Pub. Date: Feb. 19, 2026

(54) ELECTRICAL STRUCTURE AND METHOD OF MANUFACTURING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/883,890

(22) Filed: Sep. 12, 2024

Related U.S. Application Data
(62) Division of application No. 18/804,383, filed on Aug. 14, 2024.

(51) Int. Cl. H10B 12/00

(52) U.S. Cl. CPC H10B 12/00

(57) ABSTRACT

A semiconductor device includes a substrate; a first insulation layer disposed over a first surface of the substrate; a second insulation layer disposed on the first insulation layer; and an electrical contact extending through the first and second insulation layers to electrically connect to the first surface of the substrate, wherein the electrical contact includes a first portion disposed in the first insulation layer and a second portion disposed in the second insulation layer, the first portion has a first width, the second portion has a second width, and a ratio of a difference between the first width and the second width to the first width is less than 10%; at least one isolation feature extending into the substrate and disposed below the first surface of the substrate; and at least one conductive feature extending through the second insulation layer and the first insulation layer and into the substrate.

### CROSS-REFERENCE TO RELATED APPLICATION

This application is a divisional application of U.S. Non-Provisional application Ser. No. 18/804,383 filed Aug. 14, 2024, which is incorporated herein by reference in its entirety.

### TECHNICAL FIELD

The present disclosure relates to an electrical structure and a method of manufacturing the same, and more particularly, to an electrical structure including an electrical contact, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include electrical contacts for electrically interconnecting different elements. A profile of the electrical contact is a critical concern since it influences a contact resistance and an electron current transmission speed.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides an electrical structure including a substrate; a first insulation layer disposed over a first surface of the substrate; a second insulation layer disposed on the first insulation layer; an electrical contact extending through the first insulation layer and the second insulation layer to electrically connect to the first surface of the substrate, wherein the electrical contact includes a first portion disposed in the first insulation layer and a second portion disposed in the second insulation layer, the first portion has a first width, the second portion has a second width, and a ratio of a difference between the first width and the second width to the first width is less than 10%; at least one isolation feature extending into the substrate and disposed below the first surface of the substrate; and at least one conductive feature extending through the second insulation layer and the first insulation layer and into the substrate.

Another aspect of the present disclosure provides an electrical structure including a substrate; a first insulation layer disposed over a first surface of the substrate, and defining a first through hole extending through the first insulation layer, wherein the first through hole has a first width; a second insulation layer disposed on the first insulation layer and defining a second through hole extending through the second insulation layer, wherein the second through hole has a second width, and a difference between the first width and the second width is less than one tenth of the first width; an electrical contact disposed in the first through hole and the second through hole, and electrically connected to the first surface of the substrate; at least one isolation feature extending into the substrate and disposed below the first surface of the substrate; and at least one conductive feature extending through the second insulation layer and the first insulation layer and into the substrate.

Another aspect of the present disclosure provides a method of manufacturing an electrical structure. The method includes providing a stacked structure including a substrate, a first insulation layer and a second insulation layer stacked on one another, wherein at least one isolation feature is formed in the substrate and below a first surface of the substrate; forming a first hole structure extending through the first insulation layer and the second insulation layer, wherein the first hole structure exposes a portion of the substrate, and forming at least one third hole structure extending through the second insulation layer and the first insulation layer and into the substrate; and cleaning the exposed portion of the substrate using a cleaning agent so as to enlarge the first hole structure to become a second hole structure, wherein the cleaning agent includes water and hydrofluoric acid (HF), and a weight ratio of water to HF is between 500:1 and 2500:1. The method also includes forming an electrical contact in the second hole structure.

By using ultra-diluted hydrofluoric acid (HF), an electrical contact having an improved profile is formed.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic cross-sectional view of an electrical structure in accordance with some embodiments of the present disclosure.

FIG. 2 illustrates one stage of a method of manufacturing an electrical structure, in accordance with some embodiments of the present disclosure.

FIG. 3 illustrates one stage of a method of manufacturing an electrical structure, in accordance with some embodiments of the present disclosure.

FIG. 4 illustrates one stage of a method of manufacturing an electrical structure, in accordance with some embodiments of the present disclosure.

FIG. 5 illustrates one stage of a method of manufacturing an electrical structure, in accordance with some embodiments of the present disclosure.

FIG. 6 illustrates one stage of a method of manufacturing an electrical structure, in accordance with some embodiments of the present disclosure.

FIG. 7 illustrates one stage of a method of manufacturing an electrical structure, in accordance with some embodiments of the present disclosure.

FIG. 8 illustrates one stage of a method of manufacturing an electrical structure, in accordance with some embodiments of the present disclosure.

FIG. 9 illustrates one stage of a method of manufacturing an electrical structure, in accordance with some embodiments of the present disclosure.

FIG. 10 is a flowchart of a method of manufacturing an electrical structure, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

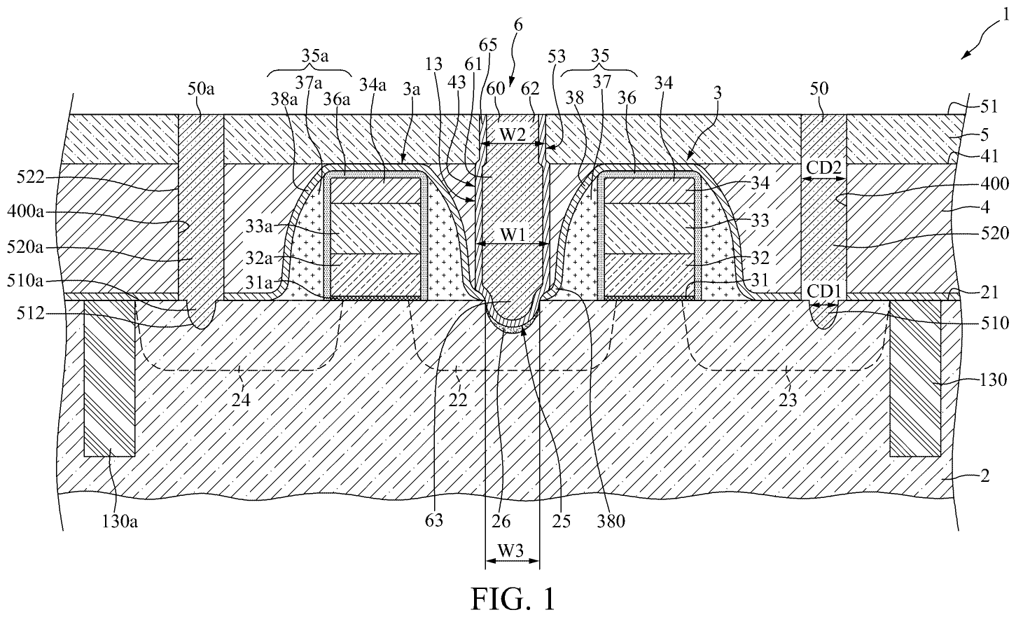

FIG. 1 is a schematic cross-sectional view of an electrical structure 1 in accordance with some embodiments of the present disclosure. In some embodiments, the electrical structure 1 may be a semiconductor structure or a semiconductor device that includes a circuit, such as a memory cell. In some embodiments, the memory cell may include a dynamic random-access memory cell (DRAM cell). In some embodiments, the electrical structure 1 may be an interconnection structure.

In addition, the electrical structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused metal-oxide semiconductor (LDMOS) transistors, high-voltage transistors, high-frequency transistors, fin field-effect transistors (FinFETs), other suitable IC components, or combinations thereof.

The electrical structure 1 may include a substrate 2 (e.g., a semiconductor substrate), a first metal-oxide-semiconductor (MOS) transistor 3, a second MOS transistor 3a, a first insulation layer 4, a second insulation layer 5, and an electrical contact 6.

In some embodiments, the substrate 2 may have a first surface 21 (e.g., a top surface). The substrate 2 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some other embodiments, the substrate 2 may include a semiconductor-on-insulator substrate, such as a silicon-on-insulator (SOI) substrate, a silicon-germanium-on-insulator (SGOI) substrate, or a germanium-on-insulator (GOI) substrate.

Depending on a fabrication stage of the IC, the substrate 2 may include various material layers (e.g., dielectric layers, semiconductor layers, and/or conductive layers) configured to form IC features (e.g., doped regions, isolation features, gate features, source/drain features, interconnect features, other features, or combinations thereof).

As shown in FIG. 1, the substrate 2 may include a drain electrode 22, a source electrode 23 and a source electrode 24. The substrate 2 may define a recess portion 25 recessed from the first surface 21 (e.g., the top surface) of the substrate 2. The recess portion 25 may be disposed in the drain electrode 22. The recess portion 25 has a third width W3. The third width W3 may be a maximum width of the recess portion 25. In addition, the substrate 2 may include a low resistance layer 26 disposed on a bottom wall of the recess portion 25. The low resistance layer 26 may include cobalt (Co) such as cobalt disilicide (CoSi₂).

The first MOS transistor 3 and the second MOS transistor 3a may each be a portion of a word line. The first MOS transistor 3 and the second MOS transistor 3a may be disposed on the first surface 21 of the substrate 2. The first MOS transistor 3 may correspond to the drain electrode 22 and the source electrode 23. The first MOS transistor 3 may include a gate oxide layer 31, a first gate conductor layer 32, a second gate conductor layer 33, an upper layer 34 and a spacer 35. The gate oxide layer 31 may be disposed on the first surface 21 of the substrate 2, and may include an oxide material for electrical insulation. The first gate conductor layer 32 may be disposed on the gate oxide layer 31, and may include a polysilicon material. The second gate conductor layer 33 may be disposed on the first gate conductor layer 32, and may include a tungsten silicide (WSiₓ) material. The first gate conductor layer 32 and the second gate conductor layer 33 may collectively form a gate electrode. The upper layer 34 may be disposed on the second gate conductor layer 33, and may include a nitride material. In some embodiments, the gate electrode may include the upper layer 34.

The spacer 35 may surround the gate electrode (including, e.g., the first gate conductor layer 32 and the second gate conductor layer 33) or may be disposed around the gate electrode. In some embodiments, the spacer 35 may include a first layer 36, a second layer 37 and a third layer 38. The first layer 36 may cover the gate oxide layer 31, the first gate conductor layer 32, the second gate conductor layer 33 and the upper layer 34, and may include a nitride material. The second layer 37 may be disposed on a lateral surface of the first layer 36 and on a portion of the first surface 21 of the substrate 2. The second layer 37 may taper upward, and may include an oxide material. The third layer 38 may cover the first layer 36 and the second layer 37. For example, the third layer 38 may cover a top surface of the first layer 36 and a top surface of the second layer 37. Thus, the second layer 37 may be sandwiched between the first layer 36 and the third layer 38. A bottom end of the third layer 38 may be disposed on the first surface 21 of the substrate 2.

Similarly, the second MOS transistor 3a may correspond to the drain electrode 22 and the source electrode 24. The second MOS transistor 3a may include a gate oxide layer 31a, a first gate conductor layer 32a, a second gate conductor layer 33a, an upper layer 34a and a spacer 35a. The gate oxide layer 31a, the first gate conductor layer 32a, the second gate conductor layer 33a, the upper layer 34a and the spacer 35a of the second MOS transistor 3a may be same as the gate oxide layer 31, the first gate conductor layer 32, the second gate conductor layer 33, the upper layer 34 and the spacer 35 of the first MOS transistor 3, respectively.

The gate oxide layer 31a may be disposed on the first surface 21 of the substrate 2, and may include an oxide material for electrical insulation. The first gate conductor layer 32a may be disposed on the gate oxide layer 31a, and may include a polysilicon material. The second gate conductor layer 33a may be disposed on the first gate conductor layer 32a, and may include a tungsten silicide (WSiₓ) material. The first gate conductor layer 32a and the second gate conductor layer 33a may collectively form a gate electrode. The upper layer 34a may be disposed on the second gate conductor layer 33a, and may include a nitride material. In some embodiments, the gate electrode may include the upper layer 34a.

The spacer 35a may surround the gate electrode (including, e.g., the first gate conductor layer 32a and the second gate conductor layer 33a) or may be disposed around the gate electrode. In some embodiments, the spacer 35a may include a first layer 36a, a second layer 37a and a third layer 38a. The first layer 36a may cover the gate oxide layer 31a, the first gate conductor layer 32a, the second gate conductor layer 33a and the upper layer 34a, and may include a nitride material. The second layer 37a may be disposed on a lateral surface of the first layer 36a and on a portion of the first surface 21 of the substrate 2. The second layer 37a may taper upward, and may include an oxide material. The third layer 38a may cover the first layer 36a and the second layer 37a. For example, the third layer 38a may cover a top surface of the first layer 36a and a top surface of the second layer 37a. Thus, the second layer 37a may be sandwiched between the first layer 36a and the third layer 38a. A bottom end of the third layer 38a may be disposed on the first surface 21 of the substrate 2.

The first insulation layer 4 may be disposed over the first surface 21 of the substrate 2. In some embodiments, the first insulation layer 4 may be disposed on the first surface 21 of the substrate 2, and may cover the first MOS transistor 3 and the second MOS transistor 3a. The first insulation layer 4 may include an oxide material such as silicon dioxide (SiO₂). A first surface 41 (e.g., a top surface) of the first insulation layer 4 may be coplanar with a top surface of the third layer 38 of the first MOS transistor 3 and a top surface of the third layer 38a of the second MOS transistor 3a. Thus, the top surface of the third layer 38 of the first MOS transistor 3 and the top surface of the third layer 38a of the second MOS transistor 3a may be exposed from the first surface 41 of the first insulation layer 4.

The first insulation layer 4 may define a first through hole 43 extending through the first insulation layer 4. The first through hole 43 has a first width W1. The first width W1 may be a maximum width of the first through hole 43. The recess portion 25 of the substrate 2 may be in communication with the first through hole 43 of the first insulation layer 4. That is, the first through hole 43 may further extend through a connecting layer 380 (connecting the third layer 38 and the third layer 38a), which contacts the first surface 21 of the substrate 2. The connecting layer 380, the third layer 38 and the third layer 38a may be a same layer. The third width W3 of the recess portion 25 may be less than the first width W1 of the first through hole 43. A width of the through hole of the connecting layer 380 may taper from the first width W1 to the third width W3.

The second insulation layer 5 may be disposed on the first insulation layer 4. The second insulation layer 5 may cover and contact the first surface 41 of the first insulation layer 4. A material of the second insulation layer 5 may be different from a material of the first insulation layer 4. The second insulation layer 5 may include a nitride material such as silicon nitride (Si₃N₄, or SiN). The second insulation layer 5 may define a second through hole 53 extending through the second insulation layer 5. The second through hole 53 of the second insulation layer 5 may be in communication with the first through hole 43 of the first insulation layer 4 so as to form a hole structure 13 (or a contact hole). A central axis of the first through hole 43 may be substantially aligned with a central axis of the second through hole 53. Thus, the hole structure 13 may extend through the first insulation layer 4 and the second insulation layer 5, and may include the first through hole 43 and the second through hole 53. In some embodiments, the hole structure 13 may further extend into the substrate 2, and may include the recess portion 25.

The second through hole 53 has a second width W2. The second width W2 may be a maximum width of the second through hole 53. The second width W2 of the second through hole 53 may be less than the first width W1 of the first through hole 43. The third width W3 of the recess portion 25 may be less than the second width W2 of the second through hole 53.

In some embodiments, a difference between the first width W1 and the second width W2 is less than one tenth of the first width W1. That is, a ratio of (W1−W2)/W1 may be less than 0.1, such as 0.09, 0.08, 0.07 or 0.06. Therefore, an offset between a sidewall of the first through hole 43 and a sidewall of the second through hole 53 may be very small. The sidewall of the first through hole 43 and the sidewall of the second through hole 53 may be approximately aligned with each other.

The electrical contact 6 may be disposed in the hole structure 13, and may extend through the first insulation layer 4 and the second insulation layer 5 to electrically connect to the first surface 21 of the substrate 2. In addition, the electrical contact 6 may further extend into the substrate 2. The electrical contact 6 may include a periphery layer 65 and a central material 60. The periphery layer 65 may be disposed on a sidewall of the hole structure 13, and may define a central hole. The central material 60 may fill the central hole defined by the periphery layer 65. The periphery layer 65 may include titanium nitride (TiN), and the central material 60 may include tungsten (W).

The electrical contact 6 may include a first portion 61, a second portion 62 and a third portion 63. The first portion 61 may be disposed in the first through hole 43 of the first insulation layer 4, and may have a first width W1. It should be noted that the first width W1 of the first portion 61 may be a maximum width of the first portion 61, and may be substantially equal to the first width W1 of the first through hole 43 of the first insulation layer 4. The first portion 61 may include a portion of the periphery layer 65 and a portion of the central material 60.

The second portion 62 may be disposed in the second through hole 53 of the second insulation layer 5, and may have a second width W2. It should be noted that the second width W2 of the second portion 62 may be a maximum width of the second portion 62, and may be substantially equal to the second width W2 of the second through hole 53 of the second insulation layer 5. The second portion 62 may include a portion of the periphery layer 65 and a portion of the central material 60. A ratio of a difference between the first width W1 and the second width W2 to the first width W1 may be less than 10%. That is, a ratio of (W1−W2)/W1 may be less than 10%, such as 9%, 8%, 7% or 6%. Therefore, an offset between a sidewall of the first portion 61 and a sidewall of the second portion 62 may be very small. The sidewall of the first portion 61 and the sidewall of the second portion 62 may be approximately aligned with each other.

The third portion 63 may be disposed in the recess portion 25 of the substrate 2, and may have a third width W3. It should be noted that the third width W3 of the third portion 63 may be a maximum width of the third portion 63, and may be substantially equal to the third width W3 of the recess portion 25 of the substrate 2. The third portion 63 may include a portion of the periphery layer 65 and a portion of the central material 60. The third width W3 may be less than the first width W1 and less than the second width W2. The low resistance layer 26 may be substantially conformal with the third portion 63 of the electrical contact 6.

The first portion 61, the second portion 62 and the third portion 63 of the electrical contact 6 may be formed integrally and concurrently so that the electrical contact 6 may be a monolithic structure. The electrical contact 6 may be disposed between the first MOS transistor 3 and the second MOS transistor 3a. The electrical contact 6 may electrically connect to an electrode of the first MOS transistor 3 and/or an electrode of the second MOS transistor 3a. As shown in FIG. 1, the electrical contact 6 may electrically connect to a common electrode (e.g., the drain electrode 22) of the first MOS transistor 3 and the second MOS transistor 3a. However, in other embodiments, the electrical contact 6 may electrically connect to a first electrode of the first MOS transistor 3 and/or a second electrode of the second MOS transistor 3a. The first electrode of the first MOS transistor 3 may be different from the second electrode of the second MOS transistor 3a.

One or more isolation features are disposed in the substrate 2. In some embodiments, the one or more isolation features include oxide or nitride and may be deposited using a (plasma) chemical vapor deposition (CVD) process, for example. In the embodiment shown in FIG. 1, there are two isolation features 130 and 130a. The isolation features 130 and 130a are disposed at either side of the electrical contact 6. In some embodiments, the isolation feature 130 extends into the substrate 2 and is disposed below the first surface 21 of the substrate 2. Further, the isolation feature 130 is disposed adjacent to the source electrode 23 and the first MOS transistor 3 and spaced apart from the first MOS transistor 3. Similarly, the isolation feature 130a extends into the substrate 2 and is disposed below the first surface 21 of the substrate 2. Further, the isolation feature 130a is disposed adjacent to the source electrode 24 and the second MOS transistor 3a and spaced apart from the second MOS transistor 3a.

The conductive features are disposed at either side of the electrical contact 6. In some embodiments, the conductive features include polysilicon and are deposited using a CVD process, for example. In the embodiment shown in FIG. 1, there are two conductive features 50 and 50a. In some embodiments, the conductive feature 50 extends through the second insulation layer 5, the first insulation layer 4, and the third layer 38 of the spacer 35, and extends into the substrate 2. Further, the conductive feature 50 is electrically connected to the source electrode 23. Similarly, the conductive feature 50a extends through the second insulation layer 5, the first insulation layer 4, and the third layer 38a of the spacer 35a, and extends into the substrate 2. Further, the conductive feature 50a is electrically connected to the source electrode 24. In some embodiments, the conductive feature 50 is disposed between the electrical contact 6 and the isolation feature 130, and the conductive feature 50a is disposed between the electrical contact 6 and the isolation feature 130a.

More particularly, the conductive feature 50 includes a lower portion 510 disposed below the first surface 21 of the substrate 2 and inserted into the substrate 2, and an upper portion 520 disposed above the first surface 21 of the substrate 2 and inserted into the second insulation layer 5, the first insulation layer 4, and the third layer 38 of the spacer 35. In more detail, the lower portion 510 of the conductive feature 50 is inserted into the source electrode 23. Similarly, the conductive feature 50a includes a lower portion 510a disposed below the first surface 21 of the substrate 2 and inserted into the substrate 2, and an upper portion 520a disposed above the first surface 21 of the substrate 2 and inserted into the second insulation layer 5, the first insulation layer 4, and the third layer 38a of the spacer 35a. In more detail, the lower portion 510a of the conductive feature 50a is inserted into the source electrode 24.

The lower portion 510 of the conductive feature 50, below the first surface 21 of the substrate 2, can have a first critical dimension CD1, and the upper portion 520 of the conductive feature 50, above the first surface 21 of the substrate 2, can have a second critical dimension CD2 greater than the first critical dimension CD1. In some embodiments, the first critical dimension CD1 gradually decreases at positions of increasing distance from the first surface 21 of the substrate 2, while the second critical dimension CD2 is constant. In particular, a peripheral surface 512 of the lower portion 510 of the conductive feature 50 is discontinuous with a peripheral surface 522 of the upper portion 520 of the conductive feature 50. Notably, the lower portion 510 and the upper portion 520 of the conductive feature 50, including polysilicon, are integrally formed. A structure of the conductive feature 50a is same as or similar to a structure of the conductive feature 50, and repeated descriptions are omitted.

The lower portion 510 of the conductive feature 50 and the lower portion 510a of the conductive feature 50a, extending into the substrate 2, can increase a contact area of the conductive feature 50 and the substrate 2. Therefore, a contact resistance through the associated conductive features 50 and 50a can be effectively reduced.

In some embodiments, the low resistance layer 26 may be disposed between the electrical contact 6 and the drain electrode 22 of the substrate 2 so as to reduce an electrical resistance of ohmic contact between the electrical contact 6 and the substrate 2. During a manufacturing process, before the low resistance layer 26 is formed, a portion of the substrate 2 that is exposed in a hole structure needs to be cleaned by a cleaning agent. In a comparative embodiment, the cleaning agent causes a large difference between a first width of a first through hole in a first insulation layer and a second width of a second through hole in a second insulation layer. Thus, the hole structure may have a “bowing profile” which causes a weak electrical contact to be formed in such hole structure. For example, such electrical contact may easily have a seam or crack formed therein. As shown in FIG. 1, the hole structure 13 may be formed according to an embodiment described below, and the difference between the first width W1 of the first through hole 43 and the second width W2 of the second through hole 53 may be reduced. Thus, the sidewall of the hole structure 13 may be substantially linear so as to facilitate a deposition process of the periphery layer 65 and a filling process of the central material 60. The electrical contact 6 may have an improved profile. A quality of the electrical contact 6 is thus improved. That is, the seam or the crack may be reduced. The electrical contact 6 may be free of seaming or cracking.

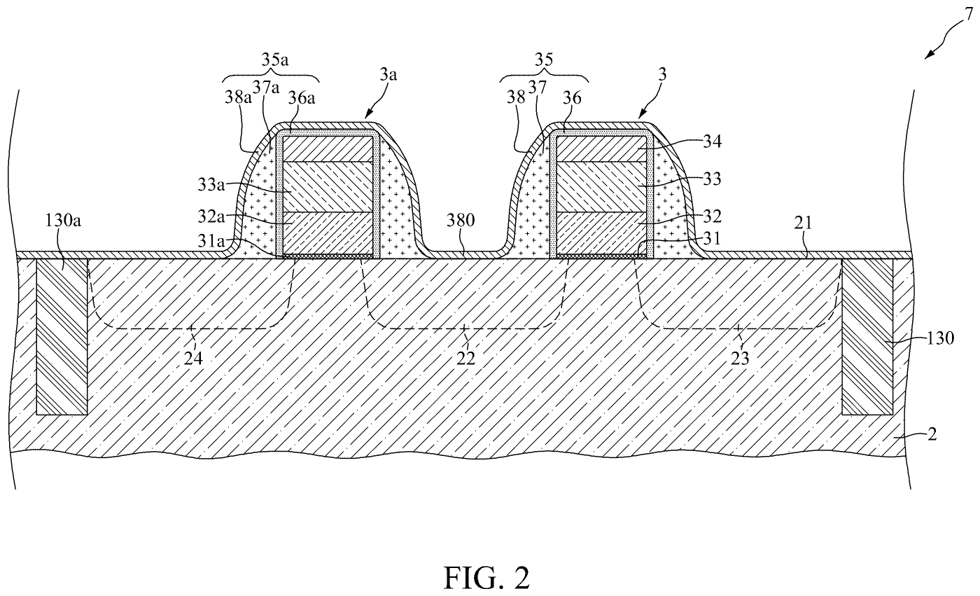

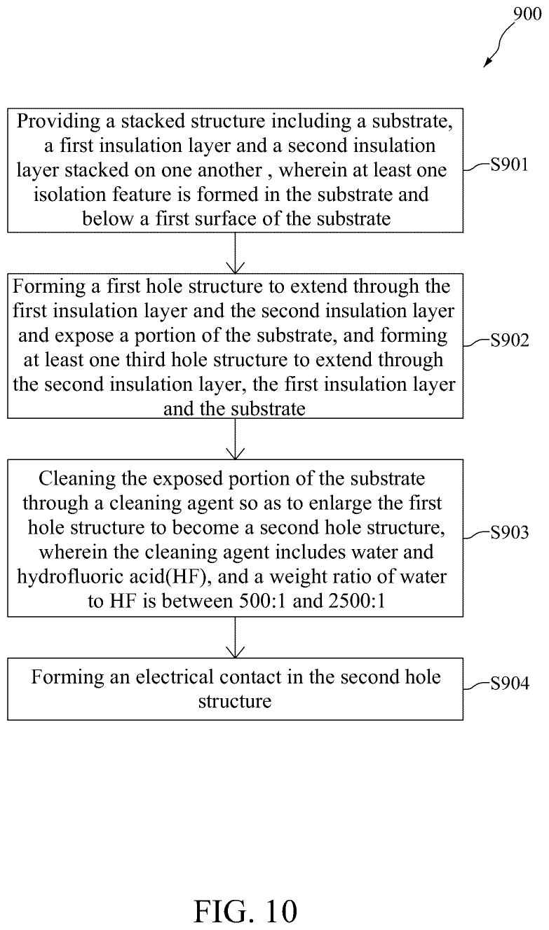

FIGS. 2 through 9 illustrate a method of manufacturing an electrical structure 1 according to some embodiments of the present disclosure. FIG. 10 illustrates a flowchart of a method 900 of manufacturing an electrical structure 1 in accordance with some embodiments of the present disclosure. Referring to FIGS. 2 through 5, a stacked structure 72 is provided. The stacked structure 72 may be manufactured as follows.

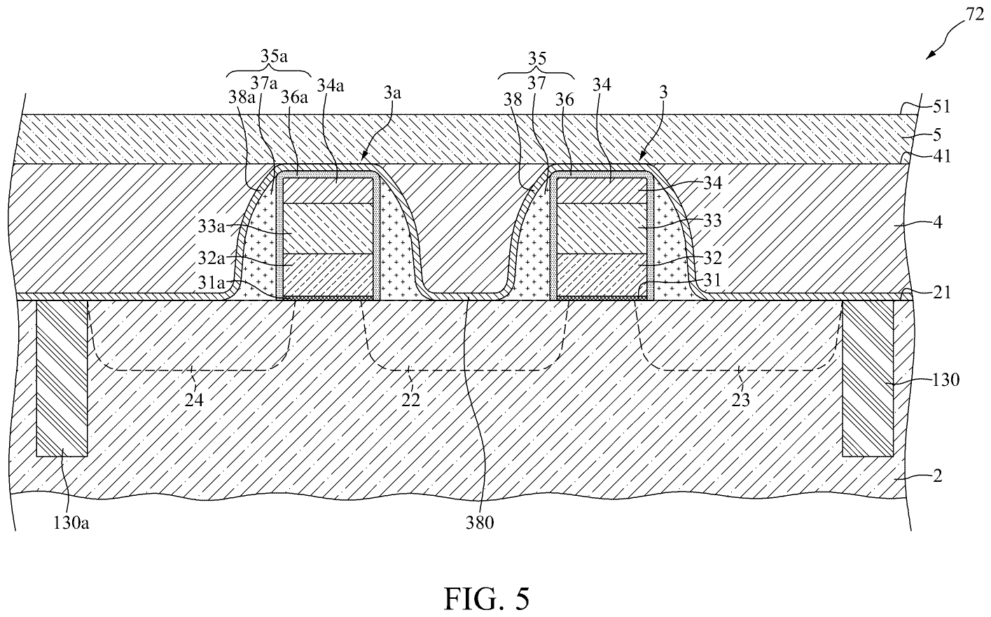

In some embodiments, the method 900 may include a step S901, in which a stacked structure is provided, wherein the stacked structure includes a substrate, a first insulation layer and a second insulation layer stacked on one another. For example, as shown in FIG. 5, the stacked structure 72 may be provided and may include the substrate 2, the first insulation layer 4 and the second insulation layer 5 stacked on one another. Referring to FIG. 2, a base portion 7 is provided. The base portion 7 may include the substrate 2, a first MOS transistor 3, a second MOS transistor 3a, an isolation feature 130 and an isolation feature 130a. The substrate 2, the first MOS transistor 3, the second MOS transistor 3a, the isolation feature 130 and the isolation feature 130a of FIG. 2 may be same as or similar to the substrate 2, the first MOS transistor 3, the second MOS transistor 3a, the isolation feature 130 and the isolation feature 130a of FIG. 1, respectively.

In some embodiments, the substrate 2 may have a first surface 21 (e.g., a top surface). The substrate 2 may include a drain electrode 22, a source electrode 23 and a source electrode 24. The substrate 2 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The first MOS transistor 3 and the second MOS transistor 3a may be formed or disposed on the first surface 21 of the substrate 2. The first MOS transistor 3 may correspond to the drain electrode 22 and the source electrode 23. The first MOS transistor 3 may include a gate oxide layer 31, a first gate conductor layer 32, a second gate conductor layer 33, an upper layer 34 and a spacer 35. The gate oxide layer 31 may be formed or disposed on the first surface 21 of the substrate 2, and may include an oxide material for electrical insulation. The first gate conductor layer 32 may be formed or disposed on the gate oxide layer 31, and may include a polysilicon material. The second gate conductor layer 33 may be formed or disposed on the first gate conductor layer 32, and may include a tungsten silicide (WSiₓ) material. The upper layer 34 may be disposed on the second gate conductor layer 33, and may include a nitride material.

The spacer 35 may surround the gate electrode (including, e.g., the first gate conductor layer 32 and the second gate conductor layer 33) or may be disposed around the gate electrode. In some embodiments, the spacer 35 may include a first layer 36, a second layer 37 and a third layer 38. The first layer 36 may cover the gate oxide layer 31, the first gate conductor layer 32, the second gate conductor layer 33 and the upper layer 34, and may include a nitride material. The second layer 37 may be disposed on a lateral surface of the first layer 36 and on a portion of the first surface 21 of the substrate 2. The second layer 37 may taper upward, and may include an oxide material. The third layer 38 may cover the first layer 36 and the second layer 37. For example, the third layer 38 may cover an outer surface of the second layer 37 and a top surface of the first layer 36. Thus, the second layer 37 may be sandwiched between the first layer 36 and the third layer 38. A bottom end of the third layer 38 may be disposed on the first surface 21 of the substrate 2.

Similarly, the second MOS transistor 3a may correspond to the drain electrode 22 and the source electrode 24. A structure of the second MOS transistor 3a may be same as or similar to that of the first MOS transistor 3, and may include a gate oxide layer 31a, a first gate conductor layer 32a, a second gate conductor layer 33a, an upper layer 34a and a spacer 35a. The gate oxide layer 31a, the first gate conductor layer 32a, the second gate conductor layer 33a, the upper layer 34a and the spacer 35a of the second MOS transistor 3a may be same as or similar to the gate oxide layer 31, the first gate conductor layer 32, the second gate conductor layer 33, the upper layer 34 and the spacer 35 of the first MOS transistor 3.

The spacer 35a may surround the gate electrode (including, e.g., the first gate conductor layer 32a and the second gate conductor layer 33a) or may be disposed around the gate electrode. In some embodiments, the spacer 35a may include a first layer 36a, a second layer 37a and a third layer 38a. The first layer 36a may cover the gate oxide layer 31a, the first gate conductor layer 32a, the second gate conductor layer 33a and the upper layer 34a, and may include a nitride material. The second layer 37a may be disposed on a lateral surface of the first layer 36a and on a portion of the first surface 21 of the substrate 2. The second layer 37a may taper upward, and may include an oxide material. The third layer 38a may cover the first layer 36a and the second layer 37a. For example, the third layer 38a may cover an outer surface of the second layer 37a and a top surface of the first layer 36a. Thus, the second layer 37a may be sandwiched between the first layer 36a and the third layer 38a. A bottom end of the third layer 38a may be disposed on the first surface 21 of the substrate 2.

A connecting layer 380 may connect the third layer 38 to the third layer 38a, and may contact the first surface 21 of the substrate 2. The connecting layer 380, the third layer 38 and the third layer 38a may be a same layer, and may be formed concurrently.

Referring to FIG. 2, the isolation feature 130 is formed extending into the substrate 2 and below the third layer 38 of the spacer 35. Further, the isolation feature 130 is formed adjacent to the source electrode 23 and spaced apart from the first MOS transistor 3. Similarly, the isolation feature 130a is formed extending into the substrate 2 and below the third layer 38a of the spacer 35a. Further, the isolation feature 130a is formed adjacent to the source electrode 24 and spaced apart from the second MOS transistor 3a.

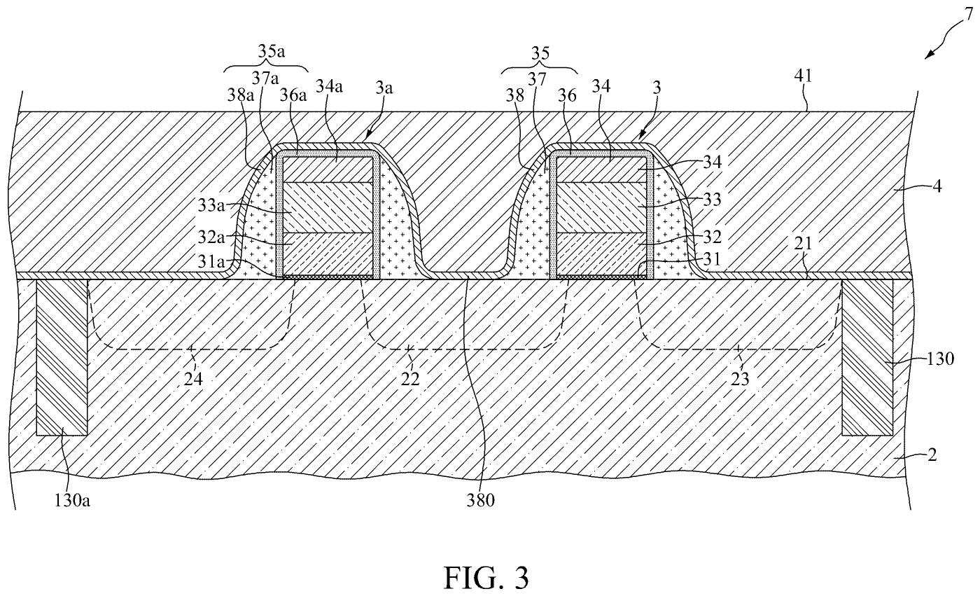

Referring to FIG. 3, the first insulation layer 4 may be formed or disposed over the first surface 21 of the substrate 2. In some embodiments, the first insulation layer 4 may be disposed on the first surface 21 of the substrate 2, and may cover the first MOS transistor 3 and the second MOS transistor 3a. A first surface 41 (e.g., a top surface) of the first insulation layer 4 may be higher than a top surface of the third layer 38 of the first MOS transistor 3 and a top surface of the third layer 38a of the second MOS transistor 3a. Thus, the top surface of the third layer 38 of the first MOS transistor 3 and the top surface of the third layer 38a of the second MOS transistor 3a may be covered by the first insulation layer 4.

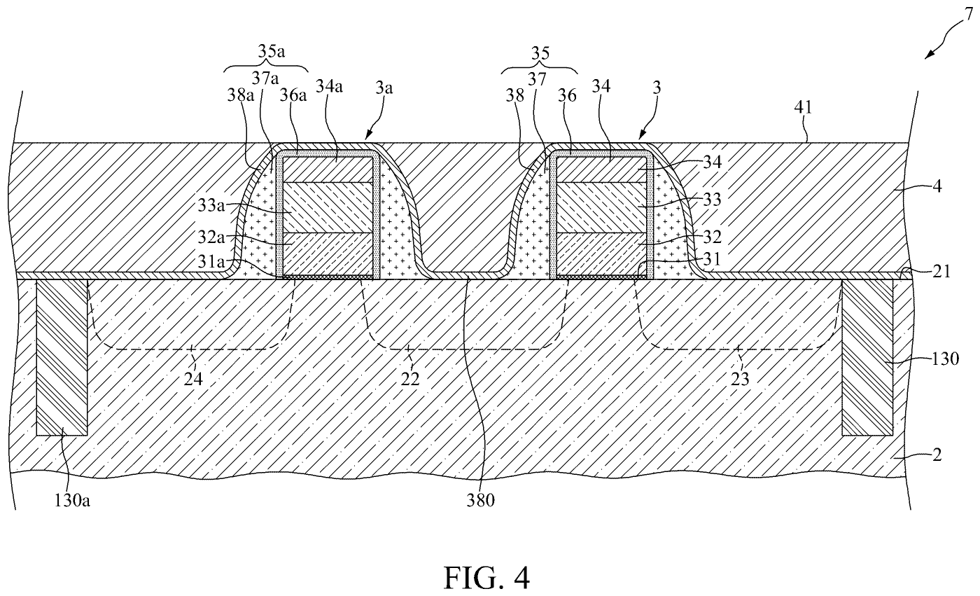

Referring to FIG. 4, the first insulation layer 4 may be thinned from the first surface 41 by, for example, grinding. Thus, an upper portion of the first insulation layer 4 may be removed, and the first surface 41 of the first insulation layer 4 may be coplanar with the top surface of the third layer 38 of the first MOS transistor 3 and the top surface of the third layer 38a of the second MOS transistor 3a. Thus, the top surface of the third layer 38 of the first MOS transistor 3 and the top surface of the third layer 38a of the second MOS transistor 3a may be exposed from the first surface 41 of the first insulation layer 4.

Referring to FIG. 5, a second insulation layer 5 may be formed or disposed on the first insulation layer 4. The second insulation layer 5 may cover and contact the first surface 41 of the first insulation layer 4. Accordingly, the stacked structure 72 may be formed. The stacked structure 72 may include the substrate 2, the first insulation layer 4 and the second insulation layer 5 stacked on one another. In addition, the stacked structure 72 may further include the first MOS transistor 3 and the second MOS transistor 3a disposed on the substrate 2 and covered by the first insulation layer 4 and the second insulation layer 5.

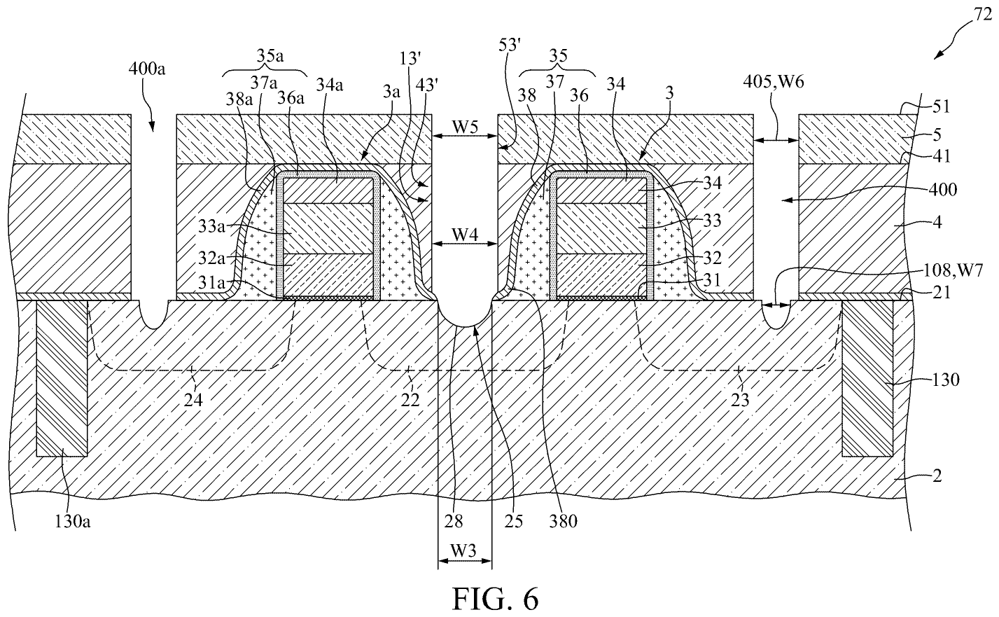

In some embodiments, the method 900 may include a step S902, in which a first hole structure is formed extending through the first insulation layer and the second insulation layer, thus exposing a portion of the substrate, and in which at least one third hole structure is formed extending through the second insulation layer and the first insulation layer and into the substrate. For example, as shown in FIG. 6, the first hole structure 13′ may be formed extending through the first insulation layer 4 and the second insulation layer 5, thus exposing the portion 28 of the substrate 2, and each of two third hole structures 400 and 400a is formed extending through the second insulation layer 5 and the first insulation layer 4 and into the substrate 2. Referring to FIG. 6, the first hole structure 13′ may be formed from a first surface 51 of the second insulation layer 5 to expose the portion 28 of the substrate 2 by, for example, dry etching. The first hole structure 13′ may extend through the first insulation layer 4 to form a fourth through hole 43′ having a fourth width W4. The first hole structure 13′ may extend through the second insulation layer 5 to form a fifth through hole 53′ having a fifth width W5. The fourth width W4 may be substantially equal to the fifth width W5. The first hole structure 13′ may be disposed between the first MOS transistor 3 and the second MOS transistor 3a. In some embodiments, the first hole structure 13′ may further extend through the connecting layer 380 and into the substrate 2 to form a recess portion 25 recessed from the first surface 21 of the substrate 2. The recess portion 25 has a third width W3. The third width W3 may be a maximum width of the recess portion 25, and may be less than the fourth width W4.

The third hole structure 400 may be formed extending through the second insulation layer 5, the first insulation layer 4, and the third layer 38 of the spacer 35, and into the substrate 2 (i.e., the source electrode 23) by, for example, dry etching. Similarly, the third hole structure 400a may be formed extending through the second insulation layer 5, the first insulation layer 4, and the third layer 38a of the spacer 35a, and into the substrate 2 (i.e., the source electrode 24) by, for example, dry etching. In some embodiments, the third hole structure 400 is disposed between the first hole structure 13′ and the isolation feature 130, and the third hole structure 400a is disposed between the first hole structure 13′ and the isolation feature 130a. Each of the third hole structures 400 and 400a has a first contact hole 405 having a substantially uniform first width W6, and a second contact hole 108 having a non-uniform second width W7. In some embodiments, the second width W7 gradually decreases at positions of increasing distance from the first surface 21 of the substrate 2.

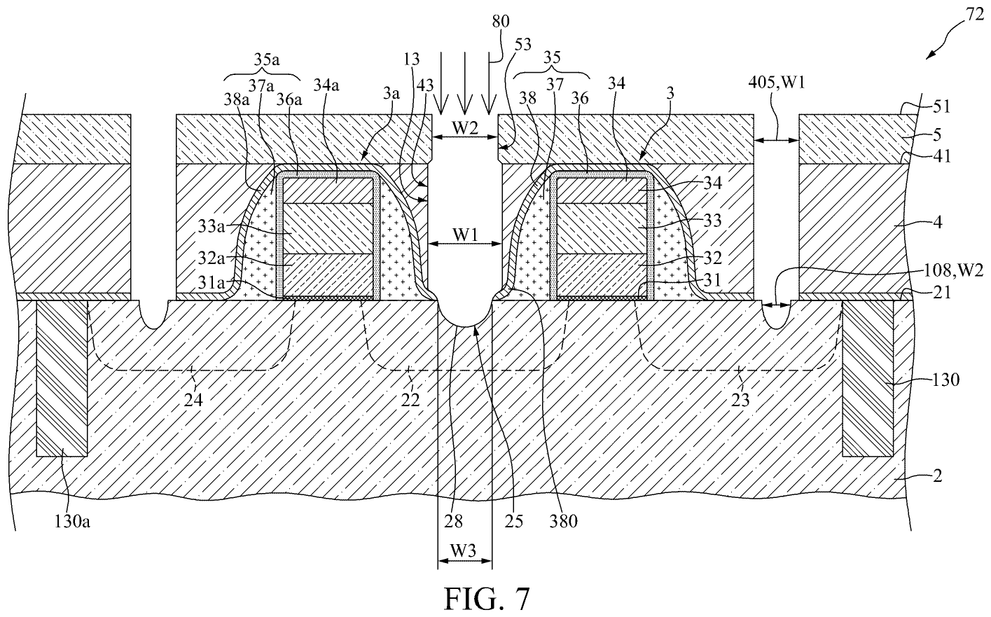

In some embodiments, the method 900 may include a step S903, in which the exposed portion of the substrate is cleaned using a cleaning agent so as to enlarge the first hole structure to become a second hole structure, wherein the cleaning agent includes water and hydrofluoric acid (HF), and a weight ratio of water to HF in the cleaning agent is between 500:1 and 2500:1. For example, as shown in FIG. 7, the exposed portion 28 of the substrate 2 may be cleaned using the cleaning agent 80 so as to enlarge the first hole structure 13′ to become the second hole structure 13. The cleaning agent 80 includes water and hydrofluoric acid (HF), and a weight ratio of water to HF in the cleaning agent 80 is between 500:1 and 2500:1. Referring to FIG. 7, the exposed portion 28 of the substrate 2 may be cleaned using the cleaning agent 80 applied into the first hole structure 13′. The cleaning agent 80 may etch the first insulation layer 4 and the second insulation layer 5 so as to enlarge the first hole structure 13′ to become the second hole structure 13. Thus, the second hole structure 13 may be formed by, for example, wet etching. The cleaning agent 80 may include water and hydrofluoric acid (HF), and a weight ratio of water to HF may be between 500:1 and 2500:1. the weight ratio of water to HF may be between 1800:1 and 2200:1, between 1000:1 and 2000:1, or between 1500:1 and 2100:1. Such cleaning agent 80 may be also referred to as an “ultra-diluted hydrofluoric acid (HF)”.

The second hole structure 13 of FIG. 7 may be similar to the hole structure 13 of FIG. 1. The second hole structure 13 may extend through the first insulation layer 4 to form a first through hole 43 (or a first enlarged through hole) having a first width W1. The second hole structure 13 may extend through the second insulation layer 5 to form a second through hole 53 (or a second enlarged through hole) having a second width W2. The first width W1 may be greater than the second width W2 since an etching rate of the cleaning agent 80 on the first insulation layer 4 is greater than an etching rate of the cleaning agent 80 on the second insulation layer 5.

In some embodiments, a difference between the first width W1 and the second width W2 is less than one tenth of the first width W1. That is, a ratio of (W1−W2)/W1 may be less than 0.1, such as 0.09, 0.08, 0.07 or 0.06. Therefore, an offset between a sidewall of the first through hole 43 and a sidewall of the second through hole 53 may be very small. The sidewall of the first through hole 43 and the sidewall of the second through hole 53 may be approximately aligned with each other.

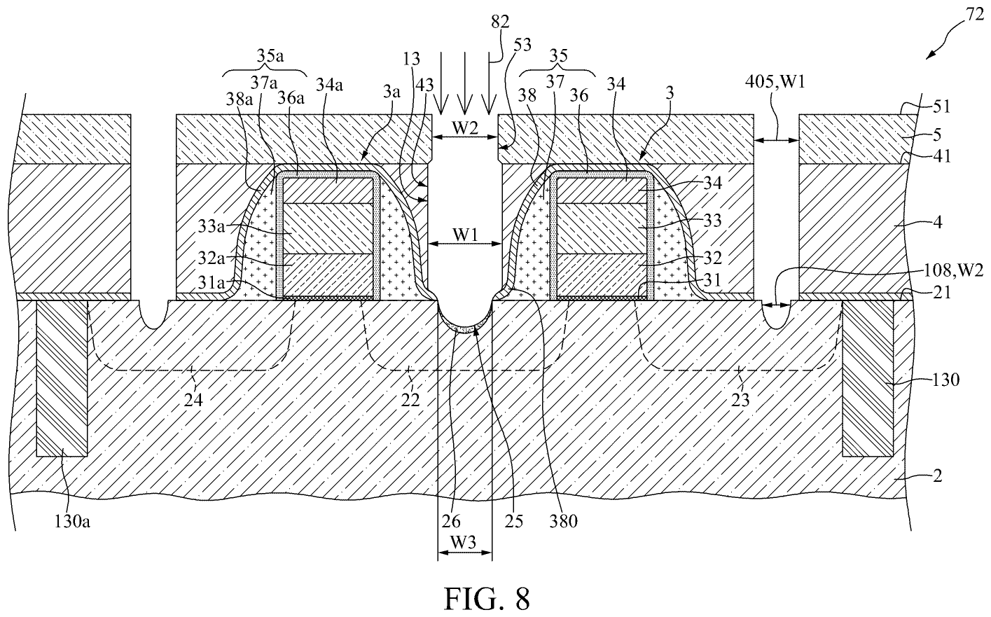

Referring to FIG. 8, a low resistance layer 26 may be formed on the cleaned exposed portion 28 of the substrate 2 by, for example, sputtering and annealing. In some embodiments, the low resistance layer 26 is formed by sputtering cobalt (Co) 82 and then annealing, so that the low resistance layer 26 may include cobalt disilicide (CoSi₂). In the present disclosure, the ultra-diluted hydrofluoric acid (HF) as stated above does not influence the formation of the low resistance layer 26.

Next, the residual cobalt (Co) may be removed by, for example, wet cleaning. Subsequently, an electrical contact 6 (shown in FIG. 1) may be formed or disposed in the second hole structure 13 as described below.

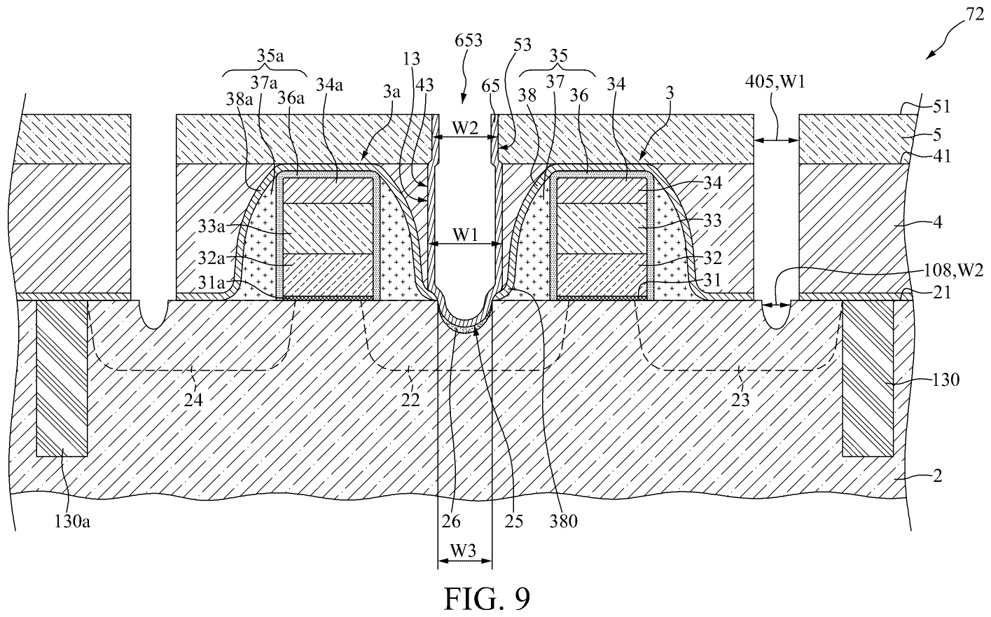

Referring to FIG. 9, a periphery layer 65 may be formed or disposed on a sidewall of the second hole structure 13 by, for example, deposition. The periphery layer 65 may define a central hole 653. The periphery layer 65 may include titanium nitride (TiN). As shown in FIG. 7, the difference between the first width W1 of the first through hole 43 and the second width W2 of the second through hole 53 may be reduced. Thus, the sidewall of the second hole structure 13 may be substantially linear so as to facilitate the deposition process of the periphery layer 65.

In some embodiments, the method 900 may include a step S904, in which an electrical contact is formed in the second hole structure 13, and in which a conductive feature is formed in each of the third hole structures. For example, as shown in FIG. 1, the electrical contact 6 is formed in the second hole structure 13, and the conductive features 50 and 50a are formed in the third hole structures 400 and 400a, respectively. Referring to FIGS. 1 and 9, a central material 60 may fill the central hole 653 defined by the periphery layer 65 so as to form the electrical contact 6. The central material 60 may include tungsten (W). The conductive features 50 and 50a, including polysilicon, are formed in the first and second contact holes 405 and 108 of each of the two third hole structures 400, 400a using a CVD process, for example. A portion of each of the conductive features 50 and 50a in the substrate 2 may have a funnel shape. In some embodiments, the conductive feature 50 is formed between the electrical contact 6 and the isolation feature 130, and the conductive feature 50a is formed between the electrical contact 6 and the isolation feature 130a. Thus, an electrical structure 1 (or a semiconductor structure) may be obtained.

As shown in FIG. 7, the difference between the first width W1 of the first through hole 43 and the second width W2 of the second through hole 53 may be reduced. Thus, the sidewall of the second hole structure 13 may be substantially linear so as to facilitate the filling process of the central material 60. As a result, a quality of the electrical contact 6 may be improved. That is, a seam or a crack of the electrical contact 6 may be reduced. The electrical contact 6 may be free of seaming or cracking. In addition, as shown in wafer electrical tests, an electrical resistance between the electrical contact 6 and the substrate 2 remains low. That is, use of the ultra-diluted hydrofluoric acid (HF) as described above does not significantly influence the electrical resistance between the electrical contact 6 and the substrate 2.

One aspect of the present disclosure provides an electrical structure including a substrate; a first insulation layer disposed over a first surface of the substrate; a second insulation layer disposed on the first insulation layer; an electrical contact extending through the first insulation layer and the second insulation layer to electrically connect to the first surface of the substrate, wherein the electrical contact includes a first portion disposed in the first insulation layer and a second portion disposed in the second insulation layer, the first portion has a first width, the second portion has a second width, and a ratio of a difference between the first width and the second width to the first width is less than 10%; at least one isolation feature extending into the substrate below the first surface of the substrate; and at least one conductive feature extending through the second insulation layer and the first insulation layer and into the substrate.

Another aspect of the present disclosure provides an electrical structure including a substrate; a first insulation layer disposed over a first surface of the substrate and defining a first through hole extending through the first insulation layer, wherein the first through hole has a first width; a second insulation layer disposed on the first insulation layer and defining a second through hole extending through the second insulation layer, wherein the second through hole has a second width, and a difference between the first width and the second width is less than one tenth of the first width; an electrical contact disposed in the first through hole and the second through hole and electrically connected to the first surface of the substrate; at least one isolation feature extending into the substrate below the first surface of the substrate; and at least one conductive feature extending through the second insulation layer and the first insulation layer and into the substrate.

Another aspect of the present disclosure provides a method of manufacturing an electrical structure. The method includes providing a stacked structure including a substrate, a first insulation layer and a second insulation layer stacked on one another, wherein at least one isolation feature is formed in the substrate below a first surface of the substrate; forming a first hole structure extending through the first insulation layer and the second insulation layer, wherein the first hole structure exposes a portion of the substrate, and forming at least one third hole structure extending through the second insulation layer and the first insulation layer and into the substrate; and cleaning the exposed portion of the substrate using a cleaning agent so as to enlarge the first hole structure to become a second hole structure, wherein the cleaning agent includes water and hydrofluoric acid (HF), and a weight ratio of water to HF in the cleaning agent is between 500:1 and 2500:1. The method also includes forming an electrical contact in the second hole structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. An electrical structure, comprising:
a substrate;
a first insulation layer disposed over a first surface of the substrate, and defining a first through hole extending through the first insulation layer, wherein the first through hole has a first width;
a second insulation layer disposed on the first insulation layer and defining a second through hole extending through the second insulation layer, wherein the second through hole has a second width, and a difference between the first width and the second width is less than one tenth of the first width;
an electrical contact disposed in the first through hole and the second through hole, and electrically connected to the first surface of the substrate;
at least one isolation feature extending into the substrate and disposed below the first surface of the substrate; and
at least one conductive feature extending through the second insulation layer and the first insulation layer and into the substrate.

2. The electrical structure of claim 1, wherein the first through hole is in communication with the second through hole.

3. The electrical structure of claim 1, wherein the electrical contact is a monolithic structure.

4. The electrical structure of claim 1, further comprising a first metal-oxide-semiconductor (MOS) transistor and a second MOS transistor disposed on the substrate, wherein the electrical contact is disposed between the first MOS transistor and the second MOS transistor.

5. The electrical structure of claim 4, wherein the electrical contact electrically connects to an electrode of the first MOS transistor, an electrode of the second MOS transistor, or electrodes of both the first and second MOS transistors.

6. The electrical structure of claim 1, wherein a material of the second insulation layer is different from a material of the first insulation layer.

7. The electrical structure of claim 1, wherein the substrate defines a recess portion in communication with the first through hole, and the electrical contact is further disposed in the recess portion.

8. The electrical structure of claim 7, wherein the recess portion has a third width less than the first width.

9. The electrical structure of claim 4, wherein the at least one isolation feature comprises two isolation features disposed at either side of the electrical contact.

10. The electrical structure of claim 9, wherein one of the two isolation features is disposed adjacent to the first MOS transistor and spaced apart from the first MOS transistor, and the other of the two isolation feature is disposed adjacent to the second MOS transistor and spaced apart from the second MOS transistor.

11. The electrical structure of claim 10, wherein the at least one conductive feature comprises two conductive features, one of the two conductive feature is disposed between the electrical contact and the isolation feature adjacent to the first MOS transistor, and the other of the two conductive feature is disposed between the electrical contact and the isolation feature adjacent to the second MOS transistor.

12. The electrical structure of claim 1, wherein the at least one conductive feature includes a lower portion disposed below the first surface of the substrate and inserted into the substrate, and an upper portion disposed above the first surface of the substrate and inserted into the second insulation layer and the first insulation layer.

13. The electrical structure of claim 12, wherein the lower portion of each of the two conductive features has a first critical dimension, and the upper portion of each of the two conductive features has a second critical dimension greater than the first critical dimension.

14. The electrical structure of claim 13, wherein the first critical dimension gradually decreases at positions of increasing distance from the first surface of the substrate, while the second critical dimension is constant.
